(19) United States
(12) Patent Application Publication
(10) Pub. No.: US 2006/0085707 A1
(43) Pub. Date: Apr. 20, 2006

(54) High speed energy conserving scan architecture

(75) Inventors: Waheed U. Khan, Austin, TX (US); Raul A. Garibay JR., Austin, TX (US); Denzil S. Fernandes, Austin, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 10/952,289

(22) Filed: Sep. 28, 2004

(51) Int. Cl. G01R 31/28

(52) U.S. Cl. 714/726

(57) ABSTRACT

A system comprising a tester and an integrated circuit, where the integrated circuit comprises a flip-flop, the flip-flop coupled to the tester and a circuit logic. The flip-flop comprises a scan input signal and a scan output signal, the signals coupled to the tester. The flip-flop also comprises multiple clock input signals.

### BACKGROUND

Before an application-specific integrated circuit (“ASIC”) is sent to a customer, the manufacturer tests the ASIC to ensure proper structural integrity. Such testing, or “scanning,” usually is conducted using a design-for-test (“DFT”) scan architecture that is built into the ASIC. One such DFT scan architecture is the MUXD scan architecture. Although the MUXD scan architecture is used to test the ASIC only before shipping, the architecture remains for the entire life of the ASIC. This permanent presence of the MUXD scan architecture in the ASIC is undesirable because the MUXD scan architecture unnecessarily consumes power and negatively impacts the functional speed of the ASIC.

A flip-flop is a basic memory component used in digital circuit design. Many digital circuits, such as the MUXD scan architecture, comprise a plurality of flip-flops that are used for timing purposes in signal processing. FIG. 1a shows an ASIC 10 having a MUXD scan architecture and comprising three such flip-flops 140A-140C. The structural integrity of the ASIC 10 may be tested by sending test signals to the flip-flops 140, receiving signals from the flip-flops 140, and comparing the received signals with expected signals.

To this end, each of the flip-flops 140 is supplied with input data signals D, SI and SE. In turn, each of the flip-flops 140 provides output data signals Q and SO. The enable signal SE determines whether input data signal D or SI is processed by the flip-flop 140. Each output signal Q is coupled to a logic 160. The multiple logics 160 are application-specific logics that perform various functions of the ASIC 10. Between the SO output of each flip-flop 140 and the SI input of a subsequent flip-flop 140 is a hold-time logic 162.

Without the presence of the hold-time logic 162 between an SO output of a flip-flop 140 and SI input of a subsequent flip-flop 140, signals traveling therebetween may arrive at the SI input faster than desired. As such, a flip-flop hold-time violation may occur. Specifically, each of the flip-flops 140 is sent the same functional clock signal. However, for example, due to clock skew, the flip-flop 140B may receive the clock signal a short time after the flip-flop 140A receives the clock signal (e.g., several picoseconds). Because the SI input value of the flip-flop 140B may change before the clock signal arrives at the flip-flop 140B, the flip-flop 140B may capture the new SI input value instead of the previous, intended value. In this way, the previous, intended value is effectively lost.

Loss of a bit value causes inaccurate structural integrity test results. The hold-time logic 162 prevents the occurrence of such problems. However, while the logic 162 may eliminate the possibility of a hold-time violation, the logic 162 is used only during scan mode. Despite inactivity during non-scan mode operations, the logic 162 still consumes leakage power, thereby draining power resources at a rate faster than necessary.

FIG. 1b shows a flip-flop 140 of FIG. 1a in greater detail. The flip-flop 140 comprises, among other things, tri-state gates 142 and a transmission gate 144. The tri-state gates 142 use the signal SE to allow either the signal D or the signal SI to pass through the transmission gate 144 to be used by the flip-flop 140. Such a tri-state gate 142 at input D is a necessary feature of a flip-flop having a MUXD-scan architecture. However, because the tri-state gates 142 perform only an inversion function, the tri-state gates 142 are considerably inefficient and cause the flip-flop 140 (and thus a device comprising the flip-flop 140) to perform at sub-optimal speed.

### SUMMARY

The problems noted above are solved in large part by a high speed, power conserving scan architecture. An exemplary embodiment may be a system comprising a tester and an integrated circuit, where the integrated circuit comprises a flip-flop, the flip-flop coupled to the tester and a circuit logic. The flip-flop comprises a scan input signal and output signal, the signals coupled to the tester, and multiple clock input signals.

Another embodiment may be a system-on-chip (“SoC”) comprising a series of flip-flops, at least some of the flip-flops comprising a scan input signal and a scan output signal, each scan output signal directly coupled to the scan input signal of a succeeding flip-flop. The flip-flops may further comprise a MOSFET coupled to the scan input signal and multiple data input signals coupled to a gate logic. The SoC also may comprise a circuit logic fixed between a pair of flip-flops.

Yet another embodiment may be a method comprising transferring test bits to a series of flip-flops, each flip-flop comprising test input signals and output signals, at least some flip-flop output signals directly connected to succeeding flip-flop input signals. The method may further comprise enabling the test bits to pass through circuit logic between the flip-flops to produce modified bits.

An exemplary embodiment of the flip-flops mentioned above may be a flip-flop comprising a plurality of flip-flop input signals, a transmission gate indirectly coupled to the plurality of flip-flop input signals, and a gate logic between the plurality of input signals and the transmission gate, wherein the gate logic is directly coupled to at least some of the plurality of input signals, and wherein the gate logic is not an inverter.

Another embodiment of the flip-flops mentioned above may be a flip-flop comprising a shifting logic comprising a plurality of clock input signals, wherein a first of the plurality of clock input signals causes a signal to be copied from a first data input signal to a first data output signal, and wherein a second of the plurality of clock input signals causes a signal to be copied from the first data output signal to a second data output signal.

### BRIEF DESCRIPTION OF THE DRAWINGS

For a detailed description of exemplary embodiments of the invention, reference will now be made to the accompanying drawings in which:

FIG. 1a shows a MUXD-based submodule comprising multiple flip-flops;

FIG. 1b shows an edge-triggered flip-flop with a tri-state gate at input D as required by MUXD-scan architecture;

FIG. 2a shows a tester coupled to a SoC, in accordance with embodiments of the invention;

FIG. 2b shows a submodule in the SoC of FIG. 2a, wherein the submodule comprises multiple flip-flops in accordance with embodiments of the invention;

FIG. 2c shows a timing diagram, during scanning mode, relating to the tester of FIG. 2a and the submodule of FIG. 2b, in accordance with embodiments of the invention;

FIG. 2d shows a flow diagram relating to a testing process in accordance with embodiments of the invention;

FIG. 3a shows internal circuitry of a flip-flop relating to FIGS. 2a-2d, in accordance with embodiments of the invention; and

FIG. 3b shows a truth table for the flip-flop of FIG. 3a, in accordance with embodiments of the invention.

### NOTATION AND NOMENCLATURE

Certain terms are used throughout the following description and claims to refer to particular system components. As one skilled in the art will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect or direct electrical connection. Thus, if a first device couples to a second device, that connection may be through a direct electrical connection, or through an indirect electrical connection via other devices and connections.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

Presented herein is a scan architecture that eliminates the need for hold-time logic between flip-flops, thus conserving power. Furthermore, the flip-flops used in this scan architecture replace the tri-state gates mentioned above with more efficient circuit logic. Implementing a more efficient circuit logic increases scanning speed by allowing a greater number of logical computations to be performed in a single clock cycle than performed in a single clock cycle of the MUXD-based architecture. This scan architecture is called Easily Migratable Scan Architecture (“EMSA”) because systems using MUXD scan architectures or other such architectures can be converted to the EMSA architecture.

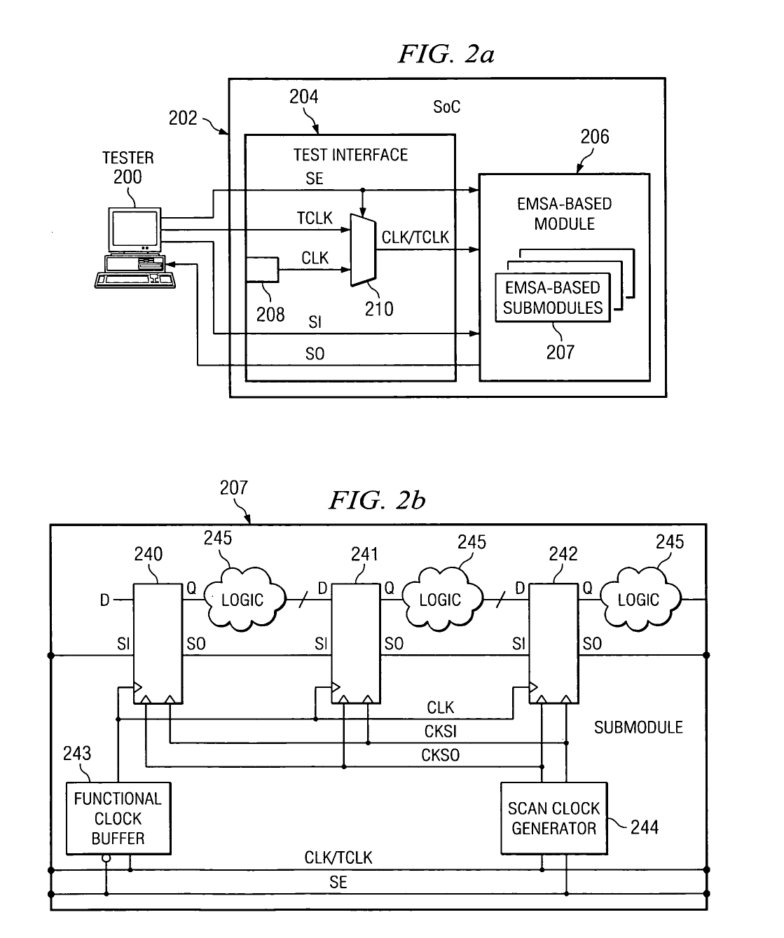

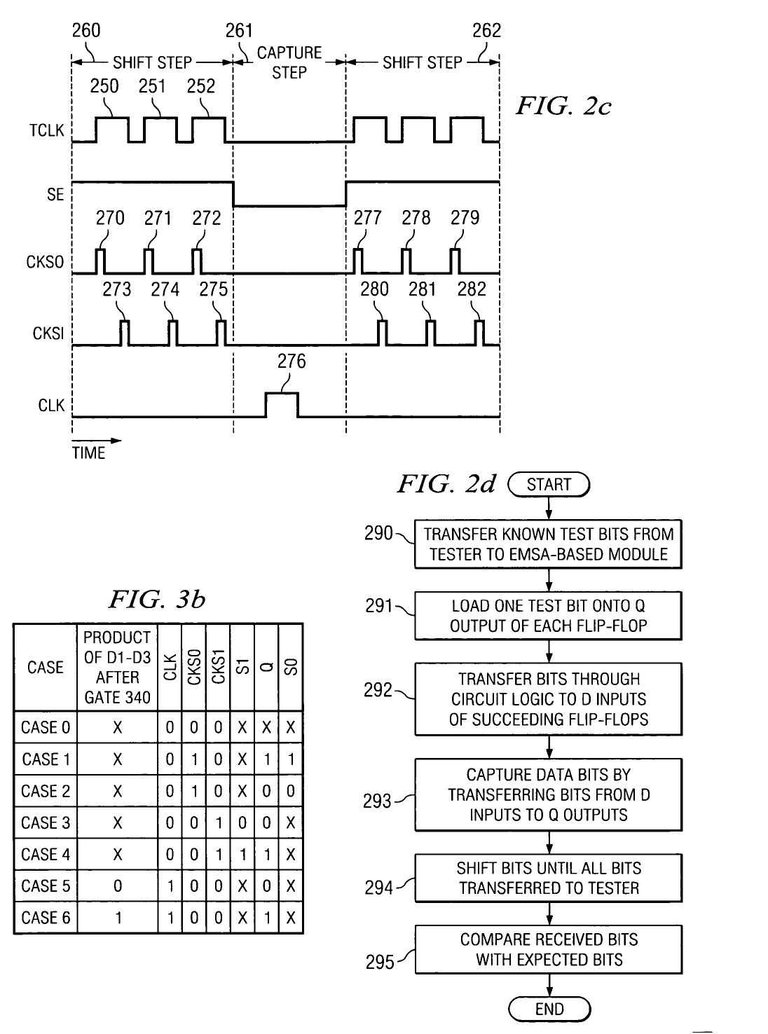

FIG. 2a shows a tester 200 coupled to a system-on-chip (“SoC”) 202 comprising a test interface 204 coupled to an EMSA-based module 206. The tester 200 uses the test interface 204 to test the structural integrity of the EMSA-based module 206 by sending signals SI to and receiving signals SO from the EMSA-based module 206. Specifically, a signal SI comprises multiple data bits that are processed by the EMSA-based module 206, resulting in the output signal SO. The tester 200 receives and compares the data bits in SO with values the tester 200 expected to receive from the EMSA-based module 206, based on calculations performed by the tester 200. If the values match, the structural integrity of the EMSA-based module 206, and therefore the SoC 202, is verified.

The test interface 204 comprises a functional clock generation logic 208 (e.g., a phased locked loop) and a multiplexer 210. The multiplexer 210, based on the enable signal SE received from the tester 200, permits either a scan test clock signal TCLK (provided by the tester 200) or the functional clock signal CLK (provided by the functional clock logic 208) to pass through the multiplexer 210. When the SE signal is not asserted, the CLK passes through the multiplexer 210. When the SE signal is asserted, the TCLK signal passes through the multiplexer 210. The clock signal selected by the multiplexer 210 is transferred on a CLK/TCLK signal line to the EMSA-based module 206. The enable signal SE and the test signal SI also are transferred to the EMSA-based module 206.

The EMSA-based module 206 comprises a plurality of flip-flops. These flip-flops are grouped into submodules 207 for various organizational and functional reasons. FIG. 2b shows a submodule 207 comprising three flip-flops 240-242 that are representative of a plurality of flip-flops in the EMSA-based module 206. The submodule 207 also comprises a functional clock buffer 243 and a scan clock generator 244. The functional clock buffer 243 receives data from signal lines CLK/TCLK and SE. When SE is not asserted, the functional clock buffer 243 provides the functional clock signal CLK to flip-flops 240-242. Conversely, when SE is asserted, the scan clock generator 244 provides the flip-flops 240-242 with the scan clock signals CKSO and CKSI. The scan clock generator 244 may comprise any suitable configuration of circuit logic that produces two separate clock signals with non-overlapping pulses, as described below and as shown by CKSO and CKSI in FIG. 2c.

Each of the flip-flops 240-242 is supplied with input data signals D and SI. Likewise, each of the flip-flops 240-242 provides output data signals Q and SO. When the enable signal SE is not asserted, data signals D and Q are used. When the enable signal SE is asserted, data signals SI and SO are used. The Q output of each flip-flop 240-242 is coupled to an ASIC-specific logic 245 that performs various functions of the EMSA-based module 206. In turn, each logic 245 is coupled to the D input of a succeeding flip-flop 240-242.

FIG. 2c shows a clock timing diagram describing the relationship between signals TCLK, SE, CKSO, CKSI and CLK as the EMSA-based module 206 is tested by the tester 200. FIG. 2d shows a process by which the EMSA-based module 206 is tested by the tester 200. Referring somewhat simultaneously to FIGS. 2a-2d, the tester 200 begins the scanning (i.e., testing) process by sending to the EMSA-based module 206 a number of known test bits corresponding to the number of flip-flops in the EMSA-based module 206 (block 290). This portion of the process is known as a shift step and is indicated as area 260 in FIG. 2c. In this example, the EMSA-based module 206 comprises three flip-flops 240-242. Thus, the tester 200 transfers three known test bits to the flip-flop 240 by way of the input signal line SI.

The tester 200 continues the testing process by causing one test bit to be loaded onto the Q output of each flip-flop 240-242 (block 291). Because the flip-flops 240-242 are arranged in a serial fashion, in order for the flip-flop 242 to have a bit on the Q output, the bit must first pass through the flip-flops 240, 241. Likewise, in order for the flip-flop 241 to have a bit on the Q output, the bit must first pass through the flip-flop 240. Accordingly, the bits are shifted through the flip-flops 240-242 in the following manner. As seen in FIG. 2c, pulses 270-272 of CKSO coincide with the high phases of the TCLK pulses 250-252, where each rising edge of TCLK triggers a CKSO pulse. Pulses 273-275 of CKSI coincide with the TCLK pulses' low phase, where each falling edge of TCLK triggers a CKSI pulse. The pulses 270-272 cause the bits on the Q output of each flip-flop 240-242 to be copied to the SO output of that flip-flop. The bits then are transferred from the SO output of that flip-flop to the SI input of a succeeding flip-flop. Each bit then is carried from the SI input of the flip-flop 240-242 to the Q output of that flip-flop with each pulse of CKSI 273-275. The tester 200 repeats this process until each flip-flop 240-242 output Q has a known bit.

To test each logic 245 of the EMSA-based module 206 for structural defects, each bit on a Q output is carried through the logic 245 between the current and succeeding flip-flop 240-242, and the results of the logic 245 are delivered to the D inputs of the succeeding flip-flops 241-242 (block 292). Once each of the three bits has been processed by a logic 245, the timing diagram of FIG. 2c enters a capture step (marked as 261), where the enable signal SE is not asserted, causing the input D and output Q signals to become active and the input SI and output SO signals to become inactive. In the capture step 261, a single pulse 276 of the functional clock signal CLK causes the Q outputs of each flip-flop 240-242 to be refreshed with a new bit value obtained from the D input of the same flip-flop 240-242 (block 293). For example, with a pulse of CLK, a flip-flop 241 having a non-asserted Q output and an asserted D input will have an asserted Q output and a D input reflecting the bit value produced by the preceding logic 245.

Once all Q output values have been refreshed in this way, the timing diagram of FIG. 2c enters another shift step (marked as 262) substantially similar to the shift step 260 described above. A CKSO pulse 277 causes the refreshed data bit on the Q output of each flip-flop 240-242 to be copied to the SO output of that same flip-flop 240-242. The last flip-flop, flip-flop 242, copies data from the Q output to the SO output. This data bit on the SO output then will be transferred to the tester 200. The remaining CKSO pulses 278, 279 and CKSI pulses 280-282 cause the remaining two bits also to be shifted through the flip-flops and transferred to the tester 200 (block 294).

Because the tester 200 is pre-programmed with information concerning the precise circuitry contained in the multiple logics 245, the tester 200 is able to predict the values the tester 200 should receive from the SO output of the last flip-flop 242. If the bit values received from the flip-flop 242 do not match the bit values predicted by the tester 200, then a structural defect may exist in the EMSA-based module 206. However, if the received and predicted bit values match, then it is likely that no structural defects exist (block 295).

Unlike the MUXD scan architecture, the SO output of each flip-flop 240 is coupled to the SI input of a succeeding flip-flop 240 without any circuit logic (i.e., used to prevent hold-time violations as in the MUXD scan architecture) therebetween, thus conserving power. The EMSA scan architecture prevents hold-time violations using the two scan clock signals CKSI and CKSO, each of which is generated by a scan clock generator 244. Because CKSO and CKSI clock pulses do not overlap, as seen in FIG. 2c, the risk of a hold time violation is substantially reduced.

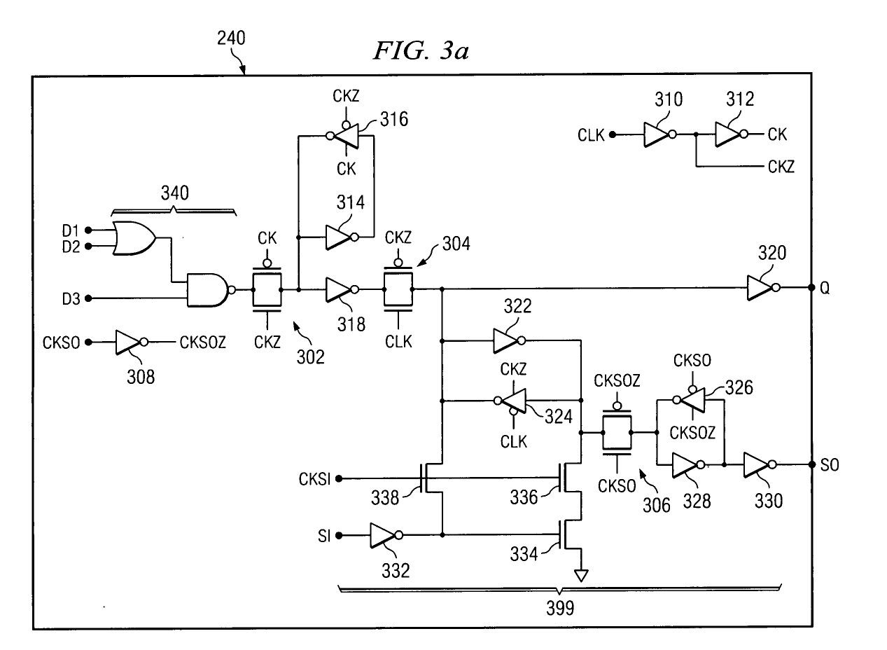

The flip-flops 240-242 may be edge-triggered flip-flops, although any type of flip-flop or memory element (e.g., latches) may be used. FIG. 3a shows the circuitry of such a flip-flop 240 (and of flip-flops 241, 242) in greater detail. The flip-flop 240 comprises a gate logic 340, transmission gates 302-306, inverter logic 308-332, and MOSFET logic 334-338. The inverters 322-332, the MOSFETs 334-338, and the transmission gate 306 may be in a shifting logic 399. The flip-flop 240 will be discussed in context of the various states of the timing diagram of FIG. 2c. As mentioned above, during the shift step 260, multiple bits are transferred to the flip-flop 240 and are shifted through the flip flops 240-242 such that one bit is loaded into each flip-flop 240-242 output Q. Next, in the capture step 261, the bits are processed by the multiple logics 245 to obtain result bits. Finally, in the shift step 262, the result bits are shifted through the flip-flops 240-242 until all the result bits are transferred to the tester 200 for evaluation.

As previously discussed, in the shift step 260, the tester 200 generates multiple TCLK pulses 250-252 while three test bits are transferred to the flip-flops 240-242. During each TCLK pulse 250-252, each flip-flop 240-242 also receives a CKSO pulse 270-272, which causes bit values at the Q output of each flip-flop 240-242 to be copied to the SO output of that flip-flop. Between each CKSO pulse 270-272, a CKSI pulse 273-275 is sent to each flip-flop 240-242, causing the value at the input SI to be copied to the outputs Q. These pulses are toggled by the scan clock generator 244 (i.e., alternately repeated) until each flip-flop 240-242 has a test bit on the Q output of that flip-flop.

For example, a first bit may be sent from the tester 200 to the SI input of flip-flop 240. CKSI pulse 273 (generated by the scan generator 244 due to the absence of a TCLK pulse) causes this first bit to be transferred to the Q output of the flip-flop 240. A second bit then may be sent to the SI input of the flip-flop 240, while the CKSO pulse 271 (generated by the scan generator 244 due to the presence of the TCLK pulse 251) causes the first bit to be transferred from the Q output of flip-flop 240 to the SO output, from which the first bit is transferred to the SI input of the flip-flop 241. CKSI pulse 274 causes the second bit to be transferred to the Q output of flip-flop 240, and the first bit to be transferred to the Q output of flip-flop 241.

A third bit then may be transferred to the SI input of the flip-flop 240, while the CKSO pulse 272 (generated due to the presence of TCLK pulse 252) causes the second bit to be copied from the Q output of flip-flop 240 to the SO output, from which the second bit is sent to the SI input of the flip-flop 241. The CKSO pulse 272 also causes the first bit to be copied from the Q output of flip-flop 241 to the SO output of flip-flop 241, from which the first bit is sent to the SI input of the flip-flop 242. Finally, the CKSI pulse 275 causes the third, second and first bits to be transferred from the Si inputs to the Q outputs of the flip-flops 240-242, respectively.

Bits are transferred from the SI inputs to the Q outputs as follows. An input SI contains the bits sent by the tester 200. During the CKSO pulse 270, input clock CKSI is not asserted. Because CKSO is asserted, CKSOZ is not asserted, due to the inverter 308. Because CLK is not asserted, CKZ is asserted due to inverter 310 and CK is not asserted due to inverters 310 and 312. Since CLK is not asserted, the transmission gate 304 is closed (i.e., not conducting), and no data inputs D1-D3 may pass through the transmission gate 304.

Because CKSO is asserted during the CKSO pulse 270, the transmission gate 306 is open (i.e., conducting). The bit value immediately before the inverter 322 is the opposite of the bit value at Q, due to the inverter 320. For example, if the bit value at Q is not asserted, then the value immediately prior to the inverter 322 is asserted. The value immediately after the inverter 322 is not asserted, and the transmission gate 306 conducts this non-asserted value to the inverter 328. The inverter 328 transforms the non-asserted signal to an asserted signal, and the inverter 330 transforms the asserted signal back to a non-asserted signal. This non-asserted signal is the output at SO, which matches the output at Q. Thus, the value at Q has effectively been copied to SO due to the CKSO pulse 270 in the shift step 260 of the timing diagram. This logic result is described in a truth table as shown in cases 1 and 2 of FIG. 3b. In situations where the signals CLK, CKSO and CKSI all are non-asserted (i.e., case 0), no bits are transferred between inputs and/or outputs.

Immediately following each CKSO pulse 270-272 in the shift step 260 is a CKSI pulse 273-275. A CKSI pulse 273-275 causes the input values at Si to be transferred to the output values at Q, as shown in cases 3 and 4 of FIG. 3b. In particular, the CKSI pulses 273-275 cause the MOSFETs 336, 338 to open. If SI is asserted, for example, then the asserted signal is converted to a not asserted signal by the inverter 332. The not asserted signal is then transferred through the MOSFET 338 and through the inverter 320, thus causing the output at Q to be an asserted signal, and thus effectively copying the bit value at the input SI to the output at Q. In this manner, bits are shifted multiple times through the flip-flops 240-242 until each of the flip-flops 240-242 has a bit at the Q output. After each flip-flop 240-242 has a bit on a corresponding Q output, bits at the Q outputs subsequently are transferred through the adjacent logic 245 and delivered to the D inputs of subsequent flip-flops. During a capture step 261, these bits at the D inputs are captured by the flip-flops 240-242 and output to the Q outputs of the flip-flops 240-242.

More specifically, during this capture step 261, the functional clock CLK is not asserted for a period of time. While CLK is not asserted, CKZ is asserted and CK is not asserted due to the inverters 310, 312. For this reason, the transmission gate 302 is opened and the result of the logic 340 is held between transmission gates 302 and 304. The functional clock CLK subsequently pulses once, causing the value between the transmission gates 302, 304 to be transferred through the transmission gate 304 and the inverter 320 to the output Q, as shown in cases 5 and 6 of FIG. 3b. In this way, the value at input D is effectively copied to the output Q.

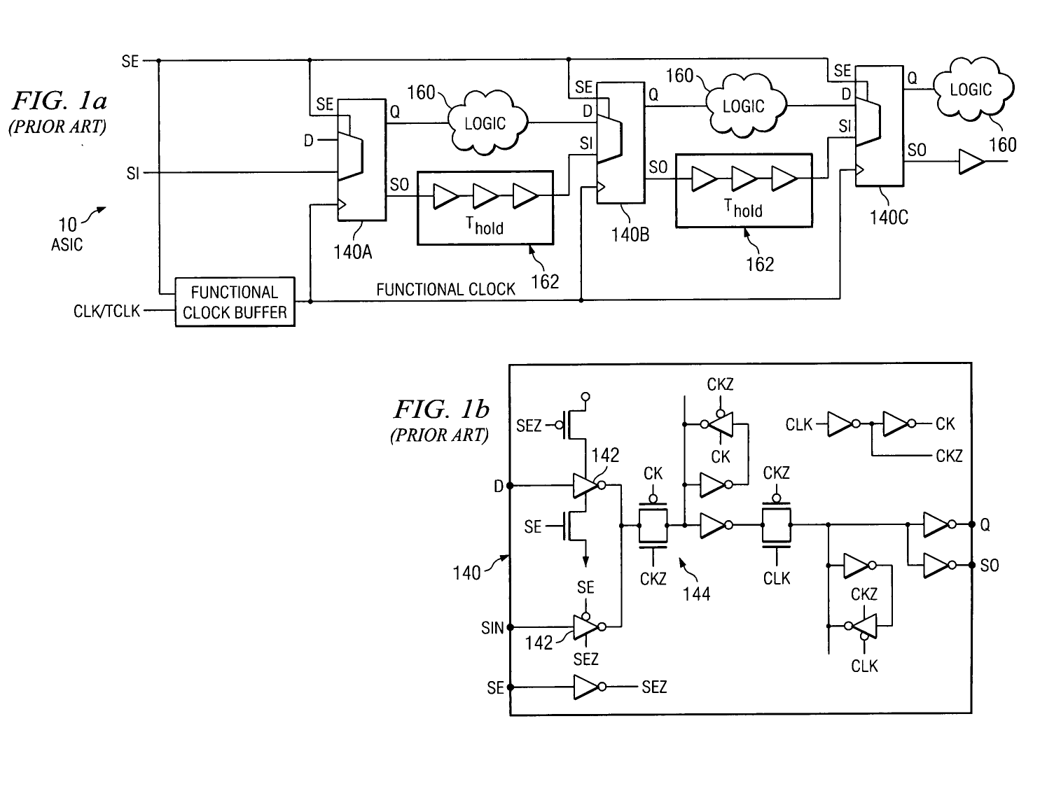

The inverter tri-state gate 142 of the flip-flop 140 in FIG. 1c is eliminated in the flip-flops 240-242. Instead, the circuit logic 340 is used (e.g., obtained from a preceding logic 245 and placed in a flip-flop 240-242). In this way, the flip-flops 240-242 actually perform other useful functional combinational logic instead of simply performing an inversion, as in the case of MUXD-scan architecture-based flip-flops 140. Embedding combinational gate logic into the flip-flops 240-242 allows the flip-flops 240-242 to perform a greater number of logic computations per clock cycle than the tri-state gate 142. Alternatively, by embedding combinational gates into the flip-flops 240-242, the logics 245 between any two succeeding flip-flops 240-242 may operate at a substantially smaller cycle time, thus allowing a device containing the flip-flops 240-242 to operate at a faster clock speed and thereby increasing the device's functional-mode speed. The logic 340 may be any type of circuit logic, such as an inverter, a 2- or 3-input NAND gate, a 2- or 3-input NOR gate, or a more complex combinational logic gate combining any such gates (e.g., a single complex combinational gate).

An example contrasting the MUXD-based architecture of FIGS. 1a-1b and the EMSA-based architecture follows. Referring to FIG. 1a, a logic 160 comprises an AND functional logic (i.e., a 2-input NAND gate followed by an inverter gate) as a final logic step prior to a flip-flop 140. The output of the AND logic directly couples to D-input of the flip-flop 140. Between its input D and output Q, the flip-flop 140 comprises the inverter tri-state gate 142, followed by a series of three additional gates: an inverter, a transmission gate and another inverter. Thus, the flip-flop 140 simply inverts an incoming signal from the AND logic of the logic 160. Thus, for example, if both of the 2-input signals into the AND logic are asserted, the signal after the AND logic at the D-input of the flip-flop 140 becomes asserted. After being processed by the tri-state gate 142 and subsequent gates inside the flop, the signal may once again become de-asserted at the output Q.

Instead of such a configuration, an ASIC implementing the EMSA-based architecture would replace the tri-state gate 142 with a single 2-input NAND gate, whose two inputs are substantially identical to those of the aforementioned AND logic and eliminate the aforementioned AND logic. In this way, the signal resulting from the new NAND gate will be identical to that resulting from the previous AND logic. However, the signal resulting from the NAND gate will be produced faster, since less logic is used to produce the signal. Because the signals are produced faster, the ASIC clock frequencies may be set higher. An ASIC implementing the EMSA-based architecture in this fashion (i.e., in thousands or even millions of flip-flops) may have an overall performance frequency substantially greater than an ASIC implementing a MUXD-based architecture or some similar scan architecture.

Referring again to FIGS. 3a and 3b, the logic 340 preferably is relocated to the flip-flop 240-242 from a preceding logic 245 (i.e., the logic 340 is ASIC-specific logic). Relocating the logic 340 from a logic 245 to a flip-flop 240-242 increases overall clock frequency because the same or a greater amount of logic is performed in a single, but shorter, clock cycle, thereby resulting in a higher clock frequency. In the example above, if the average gate delay in a given process technology is 50 picoseconds, a savings of 100 picoseconds in total execution time is realized, because after relocating the logic 340 from the logic 245 to a subsequent flip-flop 240-242, two gates are eliminated from the logic 340. Thus, if the logic 245 were the frequency-limiting critical path in an ASIC, then it could now perform at a clock cycle shortened by 100 picoseconds. Because the ASIC may comprise a considerable number of flip-flops and logic between flip-flops, relocating the logic 340 in this way may conserve a substantial amount of processing time and boost overall clock frequency (and thus the functional speed) of the ASIC.

After the capture step 261 is complete, another shift step 262 is performed to transfer the results of the multiple logics 245 through the flip-flops 240-242 and to the tester 200 for comparison with expected results. As described above, a CKSO pulse 277 causes the bit values at the Q outputs of flip-flops 240-242 to be copied to the SO output. Further CKSO and CKSI pulses cause any remaining logic 245 result values to be transferred to the tester 200 for evaluation. If the results match the values predicted by the tester 200 based on calculations performed by the tester 200, then there likely are no structural defects in the EMSA-based module 206. Conversely, if the results do not match the predicted values, then a structural defect likely exists.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A system, comprising:
a tester; and
an integrated circuit comprising a flip-flop, the flip-flop coupled to the tester and a circuit logic;
wherein the flip-flop comprises a scan input signal and a scan output signal coupled to the tester, and multiple clock input signals.

2. The system of claim 1, wherein the integrated circuit further comprises a scan clock generator coupled to at least two of the multiple clock input signals, wherein the scan clock generator generates multiple, non-overlapping clock pulses during testing of the circuit logic.

3. The system of claim 1, wherein the flip-flop comprises a gate logic directly coupled to a functional data input signal.

4. The system of claim 3, wherein the gate logic is not a tri-state gate.

5. The system of claim 3, wherein the gate logic further comprises at least one of a NOR gate, a NAND gate, a triple-input NAND gate, or a combination gate.

6. The system of claim 1, wherein the flip-flop further comprises a MOSFET coupled to the scan input signal.

7. The system of claim 1, wherein the flip-flop receives a data bit from the tester and passes the bit through the circuit logic to produce a modified bit.

8. The system of claim 7, wherein the tester compares the modified bit with an expected bit to verify the structural integrity of the circuit logic.

9. The system of claim 1, further comprising a plurality of flip-flops coupled to the tester, wherein at least some of the flip-flops comprise:
at least one functional data input signal and output signal, the data output signal coupled to the data input signal of a succeeding flip-flop by way of a circuit logic;
a scan input signal and output signal, the scan output signal directly coupled with the scan input signal of a succeeding flip-flop; and
multiple clock input signals.

10. A system-on-chip (“SoC”), comprising:
a series of flip-flops, at least some of the flip-flops comprising:
a scan input signal and output signal, each scan output signal directly coupled to the scan input signal of a succeeding flip-flop; and
multiple functional data input signals coupled to a gate logic; and
a circuit logic fixed between a pair of flip-flops.

11. The SoC of claim 10, wherein the gate logic further comprises a logic selected from a group consisting of a NAND gate, a NOR gate, a triple-input NAND gate, and a combination gate.

12. The SoC of claim 10, wherein the gate logic is not an inverter.

13. The SoC of claim 10, wherein at least one of the flip-flops enables the circuit logic to process a test bit and transfers the test bit to a tester external to the SoC.

14. A flip-flop, comprising:
a plurality of flip-flop input signals;
a transmission gate indirectly coupled to the plurality of flip-flop input signals; and
a gate logic between the plurality of input signals and the transmission gate, wherein the gate logic is directly coupled to at least some of the plurality of input signals, and wherein the gate logic is not an inverter.

15. The flip-flop of claim 14, wherein the gate logic is a logic selected from a group consisting of NAND gates, NOR gates, AND gates, OR gates, multiple-input gates, and combinational logic.

16. The flip-flop of claim 14, further comprising:
a shifting logic coupled to the gate logic; and
multiple clock input signals coupled to the shifting logic;
wherein a first of the multiple clock input signals causes a signal to be copied from a first data input signal to a first data output signal;
wherein a second of the multiple clock input signals causes a signal to be copied from the first data output signal to a second data output signal.

17. A flip-flop, comprising:
a shifting logic comprising a plurality of clock input signals;
wherein a first of the plurality of clock input signals causes a signal to be copied from a first data input signal to a first data output signal; and
wherein a second of the plurality of clock input signals causes a signal to be copied from the first data output signal to a second data output signal.

18. The flip-flop of claim 17, wherein the shifting logic is coupled to a gate logic that is directly coupled to a plurality of flip-flop input signals, and wherein the gate logic is not an inverter.

19. The flip-flop of claim 18, wherein the gate logic is a logic selected from a group consisting of NAND gates, NOR gates, AND gates, OR gates, multiple-input gates, and combinational logic.

20. The flip-flop of claim 17, wherein the first clock input signal and the first data input signal are coupled to the shifting logic using MOSFETs.

21. A method, comprising:
transferring test bits to a series of flip-flops, each flip-flop comprising test input signals and output signals, at least some flip-flop output signals directly connected to succeeding flip-flop input signals; and
enabling the test bits to pass through circuit logic between the flip-flops to produce modified bits.

22. The method of claim 21, further comprising comparing the modified bits to expected bits.

23. The method of claim 21, wherein transferring test bits to a series of flip-flops comprises using a flip-flop having multiple functional data input signals, said functional data input signals directly coupled to a gate logic.

24. The method of claim 23, wherein using the flip-flop having multiple functional data input signals, said functional data input signals directly coupled to the gate logic comprises using a gate logic that is not a tri-state gate.

25. The method of claim 23, wherein using the flip-flop having multiple functional data input signals, said functional data input signals directly coupled to the gate logic comprises using a gate logic that is selected from a group consisting of a NOR gate, a NAND gate, a triple-input NAND gate, and a combination gate.

26. The method of claim 21, wherein enabling the test bits to pass through the circuit logic comprises using a scan clock generator.

27. The method of claim 26, wherein using the scan clock generator comprises generating multiple, non-overlapping pulses.
